(19) United States
(12) Patent Application Publication
(10) Pub. No.: US 2025/0280739 A1
(43) Pub. Date: Sep. 4, 2025

(54) ELECTRONIC DEVICE

(71) Applicant: STMicroelectronics International N.V., Geneva (CH)

(72) Inventors: Aurore DUREL, Fontaine (FR); Sebastien MERMOZ, Bernin (FR)

(73) Assignee: STMicroelectronics International N.V., Geneva (CH)

(21) Appl. No.: 19/057,639

(22) Filed: Feb. 19, 2025

(30) Foreign Application Priority Data
Feb. 29, 2024 (FR) 2401994

(51) Int. Cl. H10N 70/00; H10B 63/10; H10N 70/20

(52) U.S. Cl. CPC H10N 70/021; H10B 63/10; H10N 70/231; H10N 70/883

(57) ABSTRACT

The present description concerns a method of manufacturing an electronic device comprising: the forming, on an upper surface of a support, of first elements; the forming, on the side walls of each first element, of a first layer of titanium silicon nitride; the forming of a protective layer covering the upper surface of the support and the first elements; and the planarization of the second layer so as to reach at least the level of an upper surface of the first elements.

### CROSS-REFERENCE TO RELATED APPLICATION(S)

The present disclosure is based on French patent application number FR2401994, filed on Feb. 29, 2024, entitled “Dispositif électronique” (electronic device), the content of which is hereby incorporated by reference to the maximum extend permitted by Law.

### BACKGROUND

### Technical Field

The present disclosure generally concerns electronic devices and their manufacturing methods.

### Description of the Related Art

Many manufacturing methods comprise the forming of a protective layer covering elements to be protected. Said protective layer is generally planarized in order to obtain a planar surface.

### BRIEF SUMMARY

An embodiment is directed to overcomes all or part of the disadvantages of known electronic device manufacturing methods.

An embodiment provides a method of manufacturing an electronic device comprising:
the forming, on an upper surface of a support, of first elements;
the forming, on the side walls of each first element, of a first layer of titanium silicon nitride; and
the forming of a protective layer covering the upper surface of the support and the first elements; and
the planarization of the second layer so as to reach at least the level of an upper surface of the first elements.

Another embodiment provides a device, comprising first elements bonded to an upper surface of a support, the side walls of the first element being covered with a first titanium silicon nitride layer, the device further comprising a protective layer covering the upper surface of the support and extending all the way to the upper surface of the first elements.

According to an embodiment, the forming of the first layers comprises the conformal forming of a second titanium silicon nitride layer and the anisotropic etching of the second titanium silicon nitride layer.

According to an embodiment, each first element comprises a phase-change memory cell and the support comprises a semiconductor substrate inside and on top of which selection transistors associated with the phase-change memory cells are formed.

According to an embodiment, each memory cell comprises a stack of a resistive element, of a layer of phase-change material, and of a conductive layer, each memory cell comprising an insulating layer covering the stack, the portions of the insulating layer covering the side walls of the stack of each cell being covered with the first layer.

According to an embodiment, the thickness of the second titanium silicon nitride layer is in the range from 5 nm to 20 nm.

According to an embodiment, each first element is an electronic chip.

According to an embodiment, the thickness of the second titanium silicon nitride layer is greater than 200 nm.

According to an embodiment, the first titanium silicon nitride layers extend only over the side walls of the first elements.

According to an embodiment, the planarization step is a chemical-mechanical polishing step.

According to an embodiment, the protective layer is made of an insulating material.

According to an embodiment, the planarization step is maintained until the upper surface of the first elements has been reached.

According to an embodiment, the planarization step comprises the thinning of the first elements.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1A, FIG. 1B, FIG. 1C, FIG. 1D, and FIG. 1E show an embodiment of a method of manufacturing an electronic device;

FIG. 2A, FIG. 2B, FIG. 2C, FIG. 2D, and FIG. 2E show another embodiment of an electronic device manufacturing method; and

FIG. 3A, FIG. 3B, FIG. 3C, FIG. 3D, and FIG. 3E show another embodiment of an electronic device manufacturing method.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10% or 10°, preferably of plus or minus 5% or 5°.

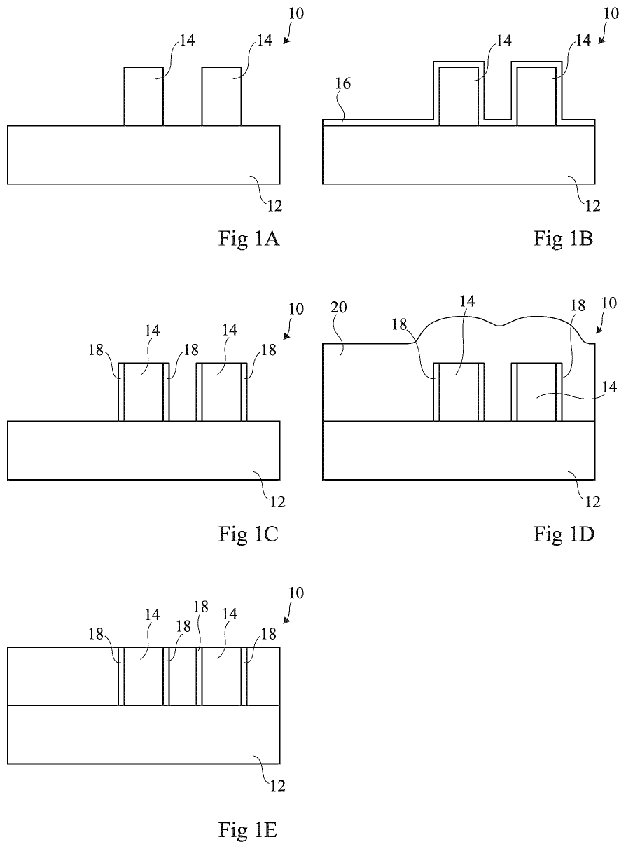

FIG. 1A, FIG. 1B, FIG. 1C, FIG. 1D, and FIG. 1E show an embodiment of a method of manufacturing an electronic device 10. More specifically, FIGS. 1A to 1E show steps, preferably successive, of a method of manufacturing device 10.

Device 10 is, for example, an electronic device intended to be integrated in electrical, electromechanical, or optoelectronic equipment. Device 10 is, for example, intended to be integrated in industrial equipment, household appliances, equipment connected via the Internet of Things (IOT), or automotive equipment.

FIG. 1A shows, schematically, a structure resulting from a step of manufacturing electronic device 10.

Device 10 comprises a support 12. Support 12 is, for example, an electronic chip. The support for example comprises a semiconductor substrate and an interconnection network, that is, a stack of insulating layers as well as conductive tracks and conductive vias. Support 12 is, for example, an electronic chip wafer. Support 12 is, for example, only a semiconductor substrate. The support is, for example, a layer made of an insulating material.

Device 10 further comprises elements 14. Elements 14 are bonded to an upper surface of support 12. Elements 14 correspond, for example, to portions of layers having been formed on support 12 and etched. Elements 14 correspond, for example, to chips or stacks of layers formed independently from support 12 and bonded to the support, more specifically to the upper surface of the support. Elements 14 are for example bonded by a bonding layer, for example an adhesive layer, by molecular bonding or by soldering.

According to an embodiment, at least two of elements 14 are identical to one another. For example, all elements 14 are identical to one another. Further, at least some of elements 14 may, for example, be different from one another. Elements 14 preferably have a substantially identical height. As an example, device 10 may comprise elements, not shown, bonded to support 12, having a height lower than the height of elements 14.

The different elements 14 are, for example, laterally surrounded by air or by another gas. Elements 14 are preferably not in contact with one another.

Elements 14 are for example not placed regularly or periodically on support 12. Device 10 thus comprises, for example, regions comprising a higher density of elements 14 than other regions of device 10.

FIG. 1B shows, schematically, a structure resulting from a step of manufacturing electronic device 10.

During this step, a layer 16 made of an alloy of titanium, silicon, and nitrogen is formed on the structure resulting from the step of FIG. 1A. Layer 16 is preferably made of titanium silicon nitride (TiSiN). Layer 16 is preferably made of a homogeneous material. Layer 16 is preferably entirely made of TiSiN.

Layer 16 is conformally formed. Layer 16 is for example formed by atomic layer deposition (ALD) or chemical vapor deposition (CVD). Layer 16 covers all the exposed walls of the structure resulting from the step shown in FIG. 1A. More specifically, layer 16 covers the side walls and the upper surface of elements 14 and the portions of support 12 not being covered by elements 14.

Layer 14, for example, has a thickness in the range from 5 nm to 750 μm. Preferably, the thickness of layer 16 is substantially constant. Preferably, the thickness of layer 16 and the distance between elements 14 are such that portions of layer 16 extending over the side walls of adjacent elements 14 are not in contact.

FIG. 1C shows, schematically, a structure resulting from a step of manufacturing electronic device 10.

The step of FIG. 1C comprises a step of anisotropic etching of layer 14. The etching is a selective etching. More precisely, the etching is a selective etching of TiSiN over the materials of support 12 and of elements 14 having layer 16 resting thereon. In other words, the etching for example etches the TiSiN at least twice, for example at least five times, for example at least ten times, faster than the materials of the support or of the elements 14 having layer 16 resting thereon.

The etching of layer 16 being anisotropic, the portions of layer 16 located on the upper surface of support 12 and on the upper surfaces of elements 14 are removed. Portions 18 of layer 16, located on the side walls of elements 14, are kept at the end of the etching.

Portions 18 preferably extend all over the side walls of elements 14. Thus, portions 18 preferably extend from the upper surface of support 12 and up to the upper surface of elements 14.

FIG. 1D shows, schematically, a structure resulting from a step of manufacturing electronic device 10.

During this step, a layer 20 is formed on the structure resulting from the step of FIG. 1C. Layer 20 is, for example, a protective layer. Layer 20 is, for example, made of a dielectric material, for example of silicon oxide.

Layer 20 is configured to entirely cover elements 14. Thus, the thickness of layer 20 is greater than the height of elements 14, that is, the distance between the upper surface of support 12 and the upper surface of elements 14.

The upper surface of layer 20 is not planar. In particular, the portions of layer 20 covering elements 14 are located further away from the support than the portions of layer 20 directly covering substrate 12.

FIG. 1E shows, schematically, a structure resulting from a step of manufacturing electronic device 10.

The step of FIG. 1E corresponds to a step of planarization of layer 20. For example, the planarization is performed by chemical mechanical polishing (CMP). The planarization is preferably maintained to reach the upper surface of elements 14.

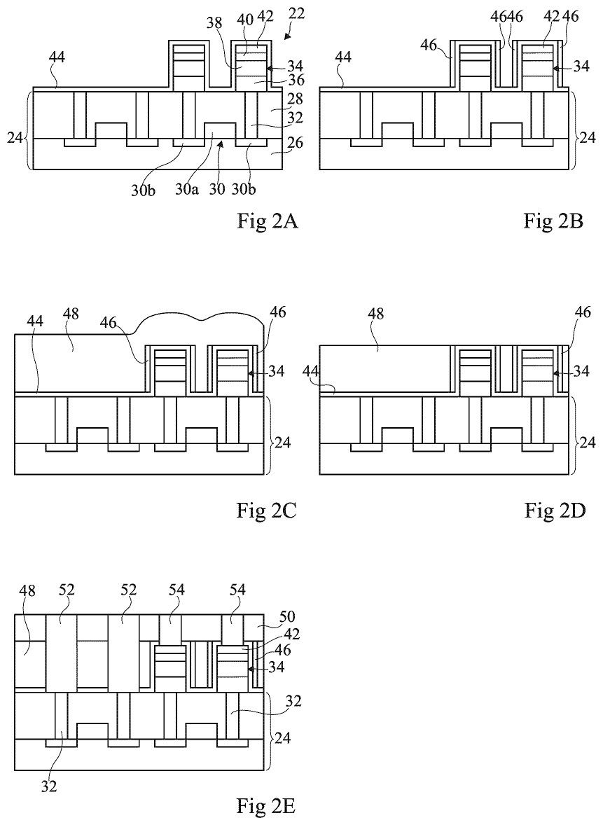

FIG. 2A, FIG. 2B, FIG. 2C, FIG. 2D, and FIG. 2E show an embodiment of a method of manufacturing an electronic device 22. The embodiment of FIGS. 2A to 2E corresponds, for example, to a more detailed example of implementation of the embodiment of the method of FIGS. 1A to 1E. More precisely, FIGS. 2A to 2E show steps, preferably successive, of a method of manufacturing device 22.

FIG. 2A schematically shows a structure resulting from a step of manufacturing electronic device 22.

The step of FIG. 2A comprises the forming of a support 24. Support 24 comprises a semiconductor substrate 26 having its upper surface covered by an insulating layer 28, for example made of silicon oxide.

Electronic components are for example formed inside and on top of substrate 26. For example, in the example of FIG. 2A, transistors 30 are formed inside and on top of substrate 26. Transistors 30 are schematically shown by their gate 30a resting on the upper surface of substrate 26 and their conduction nodes 30b located in substrate 26. Transistors 30 are, for example, selection transistors for memory cells.

Conductive vias 32 run through insulating layer 28. Vias 32 enable to form connections between substrate 26 and the upper surface of layer 28. In particular, vias 32 run through layer 28 to reach the conductive nodes 30b of transistors 30. For example, the device comprises, for each transistor 30, a via 32 running through layer 28 in such a way as to reach a source region of said transistor 30 and a via 32 running through layer 28 in such a way as to reach a drain region of said transistor 30.

Device 22 further comprises elements 34. Each element 34 corresponds to a memory cell, for example a PCM (Phase Change Memory) cell. Each element 34 comprises a stack of a resistive element 36, of a layer 38 made of a phase-change material, of a conductive layer 40 forming an upper electrode, and of a protective layer 42.

The resistive element 36 of each element 34 is in contact with a via 32. For example, the lower surface of each resistive element 36 is in contact with the upper surface of a via 32. Each resistive element 36 for example has an L shape in a cross-section plane orthogonal to the plane of FIG. 2A. Element 36 is for example made of metal, for example of tungsten or of copper.

Layer 38 is in contact with element 36. For example, the upper surface of element 36 covers and is in contact with the lower surface of layer 38. Layer 38 is for example made of a chalcogen material or of an alloy comprising a chalcogen material. For example, layer 38 is made of an alloy of germanium, antimony, and tellurium.

Layer 40 is in contact with layer 38. Preferably, the lower surface of layer 40 covers and is in contact with the upper surface of layer 38. Layer 40 is made of a metal, for example of copper.

Layer 42 is in contact with layer 40. Preferably the lower surface of layer 42 covers and is in contact with the upper surface of layer 40. Layer 42 is for example made of titanium nitride (TiN).

Elements 34 are for example arranged in an array, that is, in rows and in columns. Preferably, each element 34 comprises a resistive element 36. The elements 36 of the different elements 34 of a same row are for example separated from one another by an insulating layer. The elements 34 of a same row for example comprise common layers 38, 40, 42.

Each element 34 further comprises a passivation layer 44 covering the stack of element 36 and of layers 38, 40, 42. Layer 44 is for example made of an insulating material, for example of silicon nitride. Layer 44 covers the upper surface of layer 42 and the side walls of the stack comprising element 36 and layers 38, 40, 42. Layer 44 is for example common to all elements 34. Thus, layer 44 covers the portions of the upper surface of support 24 located between the stacks. Preferably, layer 44 conformably covers the entire structure comprising support 24 and the stacks.

Device 22 for example comprises at least one memory region, comprising a high density of elements 34, and at least another region, for example a logic region, comprising a lower density of elements 34 or comprising no element 34.

FIG. 2B shows, schematically, a structure resulting from a step of manufacturing electronic device 22. More particularly, FIG. 2B corresponds to the manufacturing portions 46.

Portions 46, like the portions 18 of the embodiment of FIGS. 1A to 1E, are made of TiSiN. Portions 46 extend over the side walls of elements 34, just as the portions 18 of the embodiment of FIGS. 1A to 1E extend over the walls of elements 14.

Portions 46 are formed, like the portions 18 of the embodiment of FIGS. 1A to 1E, by conformally forming a TiSiN layer over the entire structure resulting from the step of FIG. 1A and the anisotropic etching of said layer so as to remove the portions of said layer other than portions 46. Thus, the portions of said layer located on the portions of layer 44 covering, preferably entirely, the upper surfaces of layers 42 and the portions of said layer located on the portions of layer 44 covering the upper surface of support 24 are removed by the anisotropic etch step. Preferably, each portion 46 extends from the upper surface of layer 44 extending over support 24 and up to at least the upper surface of layer 42, preferably up to the upper surface of the portion of layer 44 extending over layer 42. Said layer for example has a thickness in the range from 1 nm to 50 nm, for example substantially equal to 10 nm.

FIG. 2C shows, schematically, a structure resulting from a step of manufacturing electronic device 22.

During this step, a layer 48 is formed on the structure resulting from the step of FIG. 2B. Layer 48 is for example a protective layer. Layer 48 is for example made of a dielectric material, for example of silicon nitride or of silicon oxide. Preferably, layer 48 is made of a material different from the material of layer 44.

Layer 48 is configured to entirely cover elements 34. Thus, the thickness of layer 48 is greater than the height of elements 34, that is, the distance between the upper surface of support 24 and the upper surface of the portion of layer 44 covering layer 42. Preferably, layer 44 is entirely covered by layer 48.

The upper surface of layer 48 is not planar. In particular, the portions of layer 48 covering elements 34 are located further away from the support than the portions of layer 48 directly covering support 24.

FIG. 2D shows, schematically, a structure resulting from a step of manufacturing electronic device 22.

The step of FIG. 2D corresponds to a step of planarization of layer 48. For example, the planarization is performed by chemical mechanical polishing (CMP). The planarization is preferably maintained until the upper surface of the portions of layer 44 covering layer 42 has been reached, that is, the surface of elements 34 most distant from support 24.

For example, the upper end of portions 46 and the upper surface of the portions of layer 44 covering layers 42 are exposed by the planarization step.

FIG. 2E shows, schematically, a structure resulting from a step of manufacturing electronic device 22.

During this step, an insulating layer 50 is formed on the structure resulting from the step of FIG. 2D. Layer 50 thus covers layer 48 and elements 34. In other words, layer 50 covers layer 48, the upper ends of portions 46 and the upper surfaces of portions of layer 44 covering layers 42.

Conductive vias 52 and 54 are then formed in such a way as to form connections with the support. Vias 52 run through layers 44, 48, 50 in such a way as to reach the ends of vias 32 not being covered by elements 34. Vias 54 run through layer 50 and layer 44 in such a way as to reach layer 42.

It could have been chosen not to form portions 46. However, the nitride density in the regions comprising elements 34, and more specifically the silicon nitride rate with respect to the silicon oxide rate, is too low to enable the planarization method to form a planar upper surface. Thus, in the absence of portions 46, the upper surface of layer 48 is not planar after the planarization method.

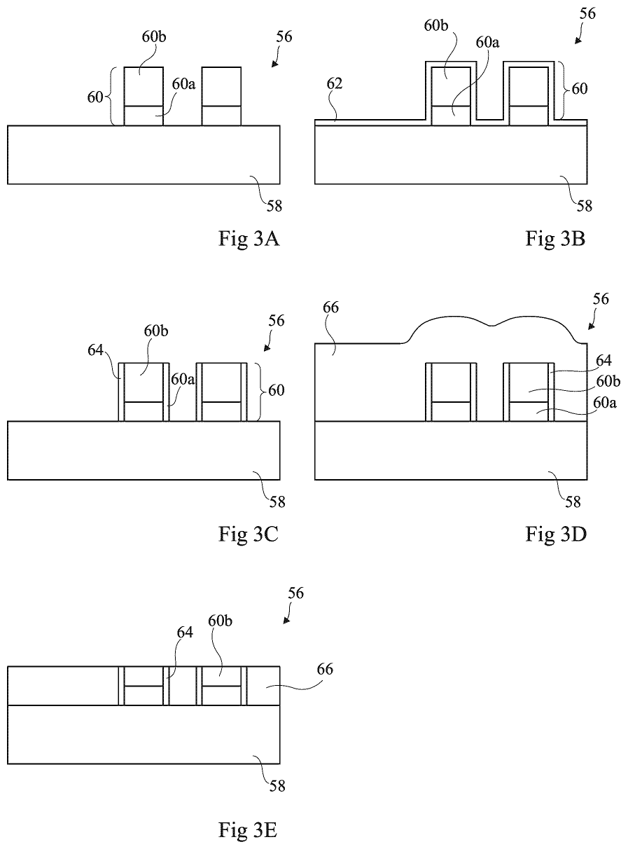

FIG. 3A, FIG. 3B, FIG. 3C, FIG. 3D, and FIG. 3E show another embodiment of a method of manufacturing an electronic device 56. The embodiment of FIGS. 3A to 3E corresponds, for example, to a more detailed example of implementation of the embodiment of the method of FIGS. 1A to 1E. More precisely, FIGS. 3A to 3E show steps, preferably successive, of a method of manufacturing device 56.

FIG. 3A shows, schematically, a structure resulting from a step of manufacturing electronic device 56.

The step of FIG. 3A comprises the forming of a support 58. Support 58 is, for example, an electronic chip. Support 58 for example comprises a semiconductor substrate and an interconnection network, that is, a stack of insulating layers as well as conductive tracks and conductive vias. Support 58 is, for example, a wafer. Support 58 is, for example, only a semiconductor substrate. Support 58 is, for example, a layer made of an insulating material.

The step of FIG. 3A further comprises the forming of elements 60. Elements 60 are bonded to an upper surface of support 58. Elements 60 correspond, for example, to portions of layers having been formed on support 58 and etched. Elements 60 correspond, for example, to chips or stacks of layers formed independently from support 58 and bonded to the support 58, more precisely to the upper surface of the support 58. Elements 60 are for example bonded by a bonding layer, for example an adhesive layer, by molecular bonding or by soldering.

For example, support 58 corresponds to a handle, for example a temporary handle, having elements 60 bonded thereto.

Each element 60 comprises, for example, a main portion 60a, corresponding to the portion closest to support 58, and a secondary portion 60b, corresponding to the portion most distant from support 58. Secondary portion 60b is intended to be thinned. Thus, secondary portion 60b preferably comprises no electronic components.

Elements 60 for example have a surface area, in top view, in the range from 1 mm² to 100 mm². Elements 60 are separated from one another by a distance in the range from 100 μm to 50 mm. The height of the elements 60 is for example greater than 500 μm, for example greater than 1 mm.

FIG. 3B shows, schematically, a structure resulting from a step of manufacturing electronic device 56.

During this step, a layer 62 of TiSiN is formed on the structure resulting from the step of FIG. 3A. Layer 62 is preferably made of a homogeneous material. Layer 62 is preferably entirely made of TiSiN.

Layer 62 is conformally formed. Layer 62 covers all the exposed walls of the structure resulting from the step of FIG. 3A. More precisely, layer 62 covers the side walls and the upper surface of elements 60 and the portions of support 58 not being covered by elements 60. Layer 62 for example has a thickness greater than 200 nm, for example greater than 500 nm.

FIG. 3C shows, schematically, a structure resulting from a step of manufacturing electronic device 56.

The step of FIG. 3C comprises a step of anisotropic etching of layer 62. The etching is a selective etching. More precisely, the etching is a selective etching of TiSiN over to the materials of support 58 and the elements 60 having layer 62 resting thereon.

The etching of layer 62 being anisotropic, the portions of layer 62 located on the upper surface of support 58 and on the upper surfaces of elements 60 are removed. Portions 64 of layer 62, located on the side walls of elements 60, are kept at the end of the etching.

Portions 64 preferably extend all over the side walls of elements 60. Thus, portions 64 preferably extend from the upper surface of support 58 and up to the upper surface of elements 60, more precisely of the portion 60b of elements 60.

FIG. 3D shows, schematically, a structure resulting from a step of manufacturing electronic device 56.

During this step, a layer 66 is formed on the structure resulting from the step of FIG. 3C. Layer 66 is, for example, a protective layer. Layer 66 is for example made of a dielectric material, for example of silicon nitride or silicon oxide.

Layer 66 is configured to entirely cover elements 60. Thus, the thickness of layer 66 is greater than the height of elements 60, that is, the distance between the upper surface of support 58 and the upper surface of the portions 60b of elements 60.

The upper surface of layer 66 is not planar. In particular, the portions of layer 66 covering elements 60 are located further away from the support than the portions of layer 66 directly covering support 58.

FIG. 3E shows, schematically, a structure resulting from a step of manufacturing electronic device 56.

The step of FIG. 3E corresponds to a step of thinning of elements 60, more precisely of the portion 60b of elements 60.

The step of FIG. 3E for example comprises a planarization step. For example, the planarization is performed by a chemical mechanical polishing (CMP). The planarization is maintained so as to thin elements 60. More precisely, the planarization is maintained until portions 64 and portions 60b are partially etched. For example, the height of each element 60 after thinning is in the range from 5 μm to 100 μm.

It could have been chosen not to form portions 64 on the side walls of elements 60. However, the thinning step, and more precisely the CMP step, would then cause a faster etching at the corners of elements 60 and would not allow a correct planarization.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

Method of manufacturing an electronic device (10, 22, 56) is summarized as including: the forming, on an upper surface of a support (12, 24, 58), of first elements (14, 34, 60); the forming, on the side walls of each first element (14, 34, 60), of a first layer (18, 46, 64) of titanium silicon nitride; the forming of a protective layer (20, 48, 66) covering the upper surface of the support and the first elements; and the planarization of the second layer so as to reach at least the level of an upper surface of the first elements.

Device (10, 22, 56), is summarized as including first elements (14, 34, 60) bonded to an upper surface of a support (12, 24, 58), the side walls of the first element being covered by a first titanium silicon nitride layer (18, 46, 64), the device further including a protective layer (20, 48, 66) covering the upper surface of the support and extending all the way to the upper surface of the first elements.

The forming of the first layers (18, 46, 64) includes the conformal forming of a second titanium silicon nitride layer (16, 62) and the anisotropic etching of the second titanium silicon nitride layer.

Each first element (34) includes a phase-change memory cell, and the support (24) includes a semiconductor substrate inside and on top of which selection transistors (30) associated with the phase-change memory cells are formed.

Each memory cell includes a stack of a resistive element (36), of a layer of phase-change material (38), and of a conductive layer (40), each memory cell includes an insulating layer (44) covering the stack, the portions of the insulating layer covering the side walls of the stack of each cell being covered by the first layer (46).

The thickness of the second titanium silicon nitride layer (44) is in the range from 5 nm to 20 nm.

Each first element (60) is an electronic chip.

The thickness of the second titanium silicon nitride layer (62) is greater than 200 nm.

The first titanium silicon nitride layers (18, 46, 64) extend only on the side walls of the first elements (14, 34, 60).

The planarization step is a chemical mechanical polishing step.

The protective layer is made of an insulating material (20, 48, 66).

The planarization step is maintained until the upper surface of the first elements has been reached.

The planarization step includes the thinning of the first elements.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing an electronic device comprising in sequence:
providing a support,
forming, on an upper surface of the support, a plurality of memory elements each comprising a stack of layers, one of which is made of a phase-change material, the memory element having a first height;
forming, on each side wall of each memory element, an etching stop element made of titanium silicon nitride, the etching stop elements having a second height substantially equal to the first height;
forming a protective layer covering the upper surface of the support and an upper surface of the memory elements and of the etching stop elements; and
planarizing the protective layer to expose the upper surface of the memory elements and the upper surface of the etching stop elements.

2. The method according to claim 1, wherein the forming of the etching stop elements includes conformally depositing a titanium silicon nitride layer on the upper surface of the support and on the side wall and the upper surface of the memory elements and anisotropic etching the titanium silicon nitride layer from the upper surface of the support and from the upper surface of the memory elements.

3. The method according to claim 2, wherein a thickness of the titanium silicon nitride layer is in the range from 5 nm to 20 nm.

4. The method according to claim 1, wherein the support comprises a semiconductor substrate comprising selection transistors formed inside and on top of substrate, an insulating layer covering the semiconductor substrate, conductive vias running through the insulating layer to form connections between substrate and the memory elements.

5. The method according to claim 1, wherein the planarizing includes chemical mechanical polishing.

6. The method according to claim 1, wherein the planarizing is continued until the upper surface of the etching stop elements is reached.

7. The method according to claim 1, wherein the planarizing includes thinning the etching stop elements.

8. The method according to claim 1, wherein each stack comprises a resistive element, the layer of phase-change material, and a conductive layer.

9. The method according to claim 1, wherein the forming of the memory elements comprises conformally depositing an insulating layer directly covering the upper surface of the support and each stack, the etch stop elements being in direct contact with sidewall portions of the insulating layer covering side walls of the stack.

10. The method according to claim 9, wherein the protective layer is made of a first dielectric material and the insulating layer is made of a second dielectric material different from the first dielectric material.

11. The method according to claim 9, wherein the planarizing of the protective layer comprises exposing the insulating layer on top of each stack and the upper surface of the etching stop elements.

12. A method of manufacturing an electronic device comprising in sequence:
providing a support,
bonding, on an upper surface of the support, a plurality of electronic elements each comprising a main portion proximal to support, and a secondary portion distal from the support, the electronic elements having a first height;
forming, on each side wall of each electronic elements, an etching stop element made of titanium silicon nitride, the etching stop elements having a second height substantially equal to the first height;
forming a protective layer covering the upper surface of the support and an upper surface of the electronic elements and of the etching stop elements; and
planarizing the protective layer to thin the electronic elements and the etching stop elements.

13. The method according to claim 12, wherein a height of the electronic elements and the etching stop elements after planarizing is in the range from 5 μm to 100 μm.

14. The method according to claim 12, wherein the first and second height is greater than 500 μm.

15. The method according to claim 12, wherein the secondary portion of each electronic elements comprises no electronic components.

16. The method according to claim 12, wherein the forming of the etching stop elements includes conformally depositing a titanium silicon nitride layer on the upper surface of the support and on the side wall and the upper surface of the first elements and anisotropic etching the titanium silicon nitride layer from the upper surface of the support and from the upper surface of the first elements.

17. The method according to claim 16, wherein the titanium silicon nitride layer has a thickness greater than 200 nm.

18. The method according to claim 12, wherein bonding the electronic elements to the support is made by an adhesive layer, by molecular bonding or by soldering.

19. The method according to claim 12, wherein the support comprises a semiconductor substrate and an interconnection network comprising a stack of insulating layers, conductive tracks and conductive vias.
